(19) United States
(12) Patent Application Publication
(10) Pub. No.: US 2009/0146734 A1
(43) Pub. Date: Jun. 11, 2009

(54) Charge Recycling (CR) in Power Gated Complementary Metal-Oxide-Semiconductor (CMOS) Circuits and in Super Cutoff CMOS (SCCMOS) Circuits

(75) Inventors: Farzan Fallah, San Jose, CA (US); Ehsan Pakbaznia, Los Angeles, CA (US); Massoud Pedram, Beverly Hills, CA (US)

Correspondence Address: BAKER BOTTS L.L.P., 2001 ROSS AVENUE, SUITE 600, DALLAS, TX, 75201-2980, US

(73) Assignee: Fujitsu Limited, Kanagawa (JP)

(21) Appl. No.: 12/263,341

(22) Filed: Oct. 31, 2008

Related U.S. Application Data
(60) Provisional application No. 61/012,836, filed on Dec. 11, 2007.

(51) Int. Cl. G05F 1/10; H03K 19/00

(52) U.S. Cl. 327/544; 326/98

(57) ABSTRACT

In one embodiment, a circuit includes a first circuit block connected to ground via a first sleep transistor, a first virtual ground node between the first circuit block and the first sleep transistor, a second circuit block connected to ground via a second sleep transistor, a second virtual ground node between the second circuit block and the second sleep transistor, and a transmission gate (TG) or a pass transistor connecting the first virtual ground node to the second virtual ground node to enable charge recycling between the first circuit block and the second circuit block during transitions by the first circuit block from active mode to sleep mode and the second circuit block from sleep mode to active mode or vice versa.

### RELATED APPLICATION

This application claims the benefit, under 35 U.S.C. §119(e), of Provisional Patent Application No. 60/012,836, filed 11 Dec. 2007, which is incorporated herein by reference.

### TECHNICAL FIELD

This disclosure relates generally to circuit design.

### BACKGROUND

As CMOS technology scales down, supply voltage decreases to avoid device failure due to high electric fields in the gate oxide and the conducting channel under the gate. Voltage scaling reduces power consumption in the circuit at least in part because of a quadratic relationship between dynamic power consumption and supply voltage, but voltage scaling increases delay at logic gates. To compensate for performance loss, transistor threshold voltages are decreased, which causes exponential increase in subthreshold leakage current.

### BRIEF DESCRIPTION OF THE DRAWINGS

FIG. 1 illustrates an example power gating structure;

FIG. 2 illustrates example voltage waveforms of a virtual ground node;

FIG. 3 illustrates an example charge-sharing structure with a switch between virtual ground and supply nodes for CR to reduce switching power consumption during active-to-sleep and sleep-to-active transitions;

FIG. 4 illustrates example use of a transmission gate (TG) to realize an example switch;

FIG. 5 illustrates an example CR configuration;

FIG. 6 illustrates another example CR configuration;

FIG. 7 illustrates example CR waveforms when CR occurs before transitioning from sleep to active mode for an example inverter chain;

FIG. 8 illustrates an example charge-sharing configuration between two arbitrary capacitors;

FIG. 9 illustrates example energy saving ratio (ESR) versus total transistor width used in at TG;

FIG. 10 illustrates example wakeup time versus TG size;

FIG. 11 illustrates an example RL equivalent model of ground used to analyze ground bounce (GB) effect in multithreshold CMOS (MTCMOS) circuits;

FIG. 12 illustrates example GB waveforms in conventional and CR structures in an example inverter chain;

FIGS. 13A-13B illustrates example CR;

FIG. 14 illustrates example CR for an SCCMOS circuit; and

FIG. 15 illustrates example percentage of total energy saving of CR MTCMOS over sleep-transistor MTCMOS (ST MTCMOS) as a function of mode-transition frequency for three different duty factor values.

### DESCRIPTION OF EXAMPLE EMBODIMENTS

Power gating may be used to reduce leakage in very large scale integration (VLSI) circuits. To achieve low power, it may be desirable to reduce energy consumption during mode transition in power gated circuits, such as for example MTCMOS or SCCMOS circuits. Particular embodiments utilize a CR technique to reduce energy consumption during mode transition in such circuits. Particular embodiments may reduce dynamic energy wasted during mode transition, while at the same time maintaining a wakeup time of the original circuit. Particular embodiments reduce a peak negative voltage value and a settling time associated with GB.

As discussed above, as CMOS technology scales down, supply voltage decreases to avoid device failure due to high electric fields in the gate oxide and the conducting channel under the gate. Voltage scaling reduces power consumption in the circuit at least in part because of a quadratic relationship between dynamic power consumption and supply voltage, but voltage scaling increases delay at logic gates. To compensate for performance loss, transistor threshold voltages are decreased, which causes exponential increase in subthreshold leakage current.

MTCMOS technology (which is called power gating or ground gating as well) provides low leakage and high performance by utilizing high speed transistors having low threshold voltages (LVT) for logic cells and low leakage devices having high threshold voltages (HVT) as sleep transistors. Sleep transistors disconnect logic cells from supply, ground, or both to reduce leakage in sleep mode. Wakeup latency and power plane integrity are concerns in MTCMOS technology.

Consider a sleep/wakeup signal supplied by an on-chip power management module. An important question is how to minimize energy consumption during mode transition, e.g., when switching from active to sleep mode or vice versa. Another important question is how to minimize time required to turn on the circuit when the wakeup signal arrives, since length of wakeup time often affects overall performance of the circuit. Moreover, a large current to ground when sleep transistors turn on may become a significant source of noise in the power distribution network, which may adversely impact performance of one or more other parts of the circuit, functionality of one or more other parts of the circuit, or both. Hence, there is a trade-off between noise generated by current flowing to ground and transition time from sleep mode to active mode. Sleep transistors cause logic cells to slow down during active mode operation of the circuit, due to a voltage drop across functionally redundant sleep transistors and an increase in threshold voltage of logic cell transistors caused by body effect. A performance penalty due to the use of a sleep transistor depends on the size of the sleep transistor and the amount of current flowing through the sleep transistor in active mode during logic transitions. Methods exist for determining an optimal sizing of sleep transistors in a particular circuit against a performance constraint. A power gating structure may support an intermediate power-saving mode and a power cut-off mode. This can be done by adding a p-type metal-oxide-semiconductor (PMOS) transistor parallel to each n-type metal-oxide-semiconductor (NMOS) sleep transistor. Applying zero voltage to a gate of the PMOS transistor may put the circuit into an intermediate power-saving mode which realizes both leakage reduction and data retention. Moreover, transitioning through the intermediate power-saving mode while changing between sleep and active modes reduces power supply or ground voltage fluctuation during power mode transitions. In cut-off mode, a gate of the PMOS transistor connects to V_{DD}.

These methods do not attempt to reduce power consumption during sleep-to-active and active-to-sleep transitions or reduce wakeup time or noise generated by the power gating structure. In contrast, particular embodiments of the present invention apply a CR technique to reduce power consumption during mode transition in a power gating structure while maintaining (or at times even improving) wakeup time. Particular embodiments help reduce GB in sleep-to-active transitions. In particular embodiments, virtual ground and virtual V_{DD} nodes quickly settle to values near V_{DD} and ground, respectively, when the MTCMOS circuit enters sleep mode. Particular embodiments utilize an accurate method of quantifying the effect of an additional sneak leakage path present in a CR MTCMOS circuit. Particular embodiments extend the use of CR to MTCMOS circuits that use a single type of sleep transistor or blocks that use different supply voltages. Particular embodiments apply CR to SCCMOS circuits.

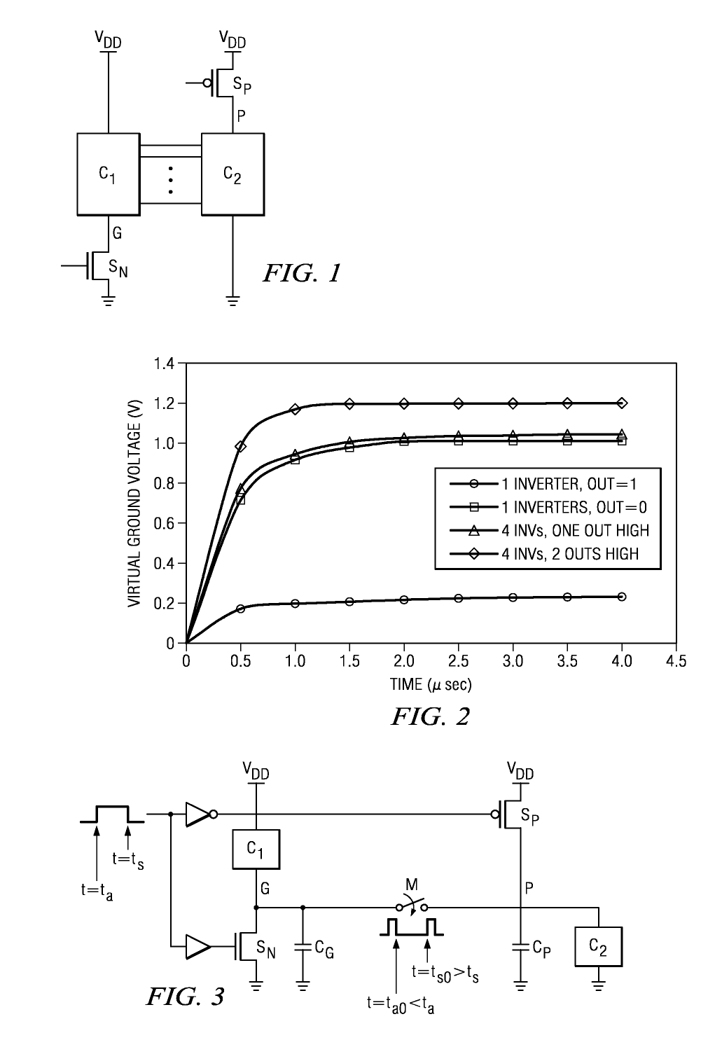

FIG. 1 illustrates an example power gating structure. The circuit includes two different blocks. An NMOS sleep transistor connecting virtual ground (e.g. Node G in FIG. 1) to ground for one of the two blocks. A PMOS sleep transistor connecting virtual V_{DD} (e.g. Node P in FIG. 1) to the supply power of the other block. In active mode, sleep transistors S_{N} and S_{P} are in linear regions and the voltages at virtual ground and virtual V_{DD} are 0 and V_{DD}, respectively. In sleep mode, sleep transistors S_{N} and S_{P} are off. Sleep transistors S_{N} and S_{P} are HVT devices, and relatively little subthreshold leakage current flows through them.

In practice, all internal nodes of the gates in block C₁ and the virtual ground node, G, will charge up to a voltage close to V_{DD}, since G is floating and leakage current causes its voltage level to rise toward V_{DD}. Similarly, if the sleep period is long enough, all internal nodes of C₂ and the virtual supply node, P, will discharge to a voltage close to 0.

Consider subcircuit C₁ in FIG. 1. The only time when the assumption that virtual ground charges up to a value close to V_{DD} is invalid is when the outputs of all logic cells in C₁ are at logic 1 (e.g. the pull-down sections of all cells are off) before an active-to-sleep transition occurs. However, this rarely happens in practice because, if at least one cell in C₁ has an output value at logic 0 (e.g. its pull-down section is on) before the active-to-sleep transition and the sleep period is sufficiently long, the steady-state value for the virtual ground voltage in sleep mode will be close to V_{DD}. Since a subcircuit typically includes tens of logic cells, the probability of at least one of them having logic 0 at its output (before entering sleep mode) is almost 1. Therefore, the voltage at virtual ground for subcircuit C₁ will rise and approach V_{DD} after sufficient time in sleep mode.

FIG. 2 illustrates example voltage waveforms of a virtual ground node in four different cases. Each case uses an n-type metal-oxide-semiconductor (NMOS) sleep transistor (the use of a p-type metal-oxide-semiconductor (PMOS) sleep transistor produces similar results, except the corresponding output states are reversed). In the first case, subcircuit C₁ includes a single inverter cell. The output of the inverter cell is forced to logic 1 before entering sleep mode. As FIG. 2 shows, after entering sleep mode, the virtual ground voltage of the inverter cell rises to approximately 200 mV, which is much less than V_{DD} of 1.2 V. In the next case, the output of the inverter in the same subcircuit C₁ is forced to logic 0. The virtual ground voltage rises to approximately 0.95 V, which is close to V_{DD} and a suitable level for CR. In the next two cases, C₁ includes four inverter cells, each driving by an input of C₁. In the first of these two cases, three of the inverter outputs are 1 and one inverter output is 0. The virtual ground voltage rises to even a higher level than the second case above, resulting in a final steady sate voltage level of approximately 1 V, which is again suitable for CR. In the last case, two inverter outputs are set to logic 1 and the others are set to logic 0. After entering sleep mode, the virtual ground node should rise and achieve a level even closer to V_{DD}. FIG. 2 confirms this: the top waveform shows the virtual ground of the subcircuit C₁ reaches a level of nearly 1.2 V. As long as a relatively large number of logic cells that use an NMOS sleep transistor are in a subcircuit, the probability that one of the cells will have a logic 0 output value before entering sleep mode is high (in fact probably close to one) so the virtual ground voltage of such a subcircuit will gradually rise and stabilize to a level near V_{DD}. This stabilization occurs after a relatively short period of sleep time (usually on the order of microseconds) which provides an opportunity for CR between this subcircuit and another one that uses a PMOS sleep transistor. The use of a PMOS sleep transistor produces similar results, with the virtual V_{DD} node discharging to 0 during sleep mode.

In practice, in a circuit block that uses an NMOS sleep transistor, the number and sizes of logic cells with output 0 is usually large enough to enable the virtual ground voltage of the circuit after it enters sleep mode to rise to a value close to V_{DD}. The same holds for a virtual V_{DD} voltage of a circuit block that uses a PMOS sleep transistor dropping to a value close to the ground voltage level after the circuit enters sleep mode. Herein, where appropriate, we assume that the virtual ground and V_{DD} voltages of circuits using NMOS and PMOS transistors will change to V_{DD} and ground levels, respectively, after entering and staying in sleep mode long enough. Particular embodiments provide energy savings during mode transitions.

In particular embodiments, when the sleep-to-active transition edge arrives at the gates of the sleep transistors in an MTCMOS circuit, the voltage of G starts to fall toward 0 and the voltage of P starts to rise toward V_{DD}. If we denote the total effective capacitance in the virtual ground and virtual V_{DD} nodes by C_{G} and C_{P}, respectively, during the active-to-sleep transition, C_{G} charges up from 0 to V_{DD}, while CP discharges from V_{DD} to 0. The situation is reversed for the sleep-to-active transition, e.g., in this case C_{G} discharges from V_{DD} to 0, while C_{P} charges to V_{DD} from its initial value of 0. In terms of energy dissipation, these charge and discharge events on the virtual ground and virtual V_{DD} nodes are wasteful.

Particular embodiments reduce energy consumption when switching between active and sleep modes of the circuit. Particular embodiments implement a charge-sharing switch between the virtual ground and supply nodes for CR (as FIG. 3 illustrates by way of example) to reduce switching power consumption during active-to-sleep and sleep-to-active transitions. In particular embodiments CR operates as follows. The charge-sharing switch turns on (i) before the sleep transistors turn on to go from sleep to active mode and/or (ii) after the sleep transistors turn off to go from active to sleep mode. Turning on the switch at the end of sleep mode when the circuit is about to go from sleep to active mode allows charge sharing between the charged capacitance C_{G} and the discharged capacitance C_{P}. After CR completes, the common voltage of the virtual ground and virtual supply is αV_{DD}, where α is a positive real number less than 1. In particular embodiments, the value of α depends on the relative sizes of C_{G} and C_{P}. This step reduces the power consumed due to switching the sleep transistors on and off. After finishing charge recycling and turning on the sleep transistors, the voltage at virtual ground changes from αV_{DD} to 0, and the voltage at virtual supply changes from αV_{DD} to V_{DD}. In contrast, in a conventional MTCMOS circuit, the transitions are from V_{DD} to 0 and from 0 to V_{DD} at the virtual ground and virtual V_{DD} nodes, respectively. This CR technique similarly helps reduce power consumption during transition from active mode to sleep mode.

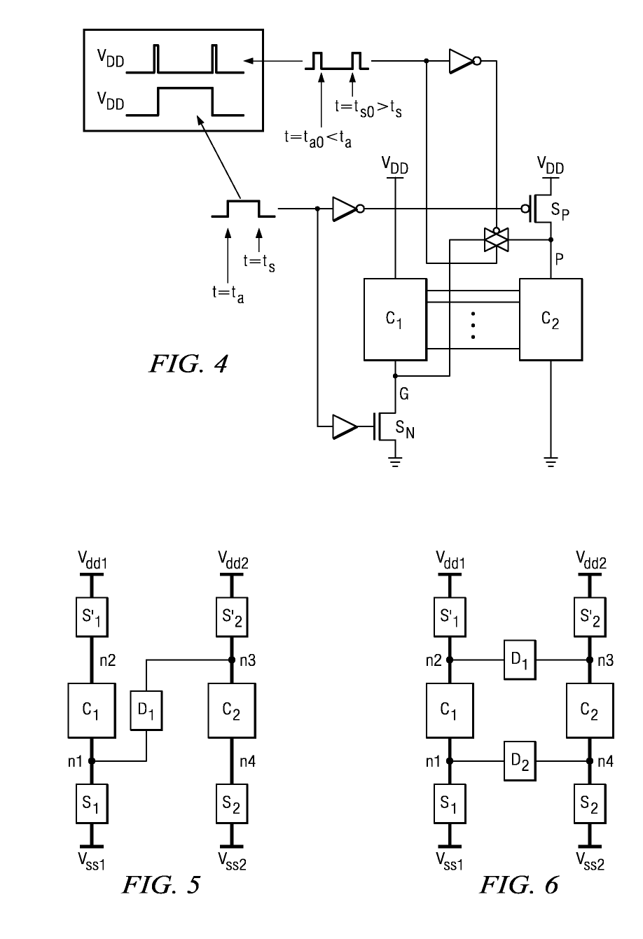

Particular embodiments use a TG to realize a switch, as FIG. 4 illustrates by way of example. Particular embodiments use other circuit realizations of switches, such as for example pass transistors. Achieving full charge sharing between the floating virtual ground and virtual V_{DD} nodes may be easier with a TG.

FIG. 5 illustrates an example CR configuration. In the CR configuration in FIG. 5, V_{DD1} and V_{DD2} may but need not be equal. Similarly, Vₛₛ₁ and Vₛₛ₂ may but need not be equal. Vₛₛ₁ may but need not be ground, and Vₛₛ₂ may but need not be ground. S₁ and S′₂ may each be a switch (e.g. a PMOS transistor, an NMOS transistor, or a transmission gate) or a switch in parallel with a clip circuit (e.g. a diode). S₂ and S′₁ may each be a switch (e.g. a PMOS transistor, an NMOS transistor, or a transmission gate), a switch in parallel with a clip circuit (e.g. a diode), or a wire. D₁ is a switch (e.g. a PMOS transistor, an NMOS transistor, or a transmission gate) or a switch in series with a clip circuit (e.g. a diode). C₁ and C₂ may but need not include memory elements.

In the CR configuration in FIG. 5, at least one of the following two conditions holds:
At the same time or shortly before or shortly after C₁ switches from sleep mode to active mode, C₂ switches from sleep mode to active mode; furthermore, when C₁ switches from sleep mode to active mode, the voltage at Node n1 is higher than the voltage at Node n3.
At the same time or shortly before or shortly after C₂ switches from active mode to sleep mode, C₁ switches from active mode to sleep mode; furthermore, when C₂ switches from active mode to sleep mode, the voltage at Node n3 is higher than the voltage at Node n1.

Particular embodiments perform CR in the configuration illustrated by FIG. 5 by turning on D₁ for a period of time shortly before both C₁ and C₂ enter active mode or by turning on D₁ for a period of time shortly after both C₁ and C₂ enter sleep mode. During CR, neither the output of C₁ nor the output of C₂ is used.

FIG. 6 illustrates another example CR configuration. In the CR configuration in FIG. 6, V_{DD1} and V_{DD2} may but need not be equal. Similarly, Vₛₛ₁ and Vₛₛ₂ may but need not be equal. Vₛₛ₁ may but need not be ground, and Vₛₛ₂ may but need not be ground. S₁ and S′₁ may each be a switch (e.g. a PMOS transistor, an NMOS transistor, or a transmission gate), a switch in parallel with a clip circuit (e.g. a diode), or a wire, but S₁ and S′₁ may not both be wires. S₂ and S′₂ may each be a switch (e.g. a PMOS transistor, an NMOS transistor, or a transmission gate), a switch in parallel with a clip circuit (e.g. a diode), or a wire, but S₂ and S′₂ may not both be wires. D₁ and D₂ are each a switch (e.g. a PMOS transistor, an NMOS transistor, or a transmission gate), a switch in series with a clip circuit (e.g. a diode), or an open circuit, but D₁ and D₂ may not both be open circuit. C₁ and C₂ may but need not include memory elements. If D₁ is not an open circuit, S′₁ and S′₂ are not short circuit. If D₂ is not an open circuit, S₁ and S₂ are not short circuit.

In the example CR configuration in FIG. 6, at least one of the following four conditions holds:
D1 is not an open circuit and, at the same time or shortly before or shortly after C1 switches from sleep mode to active mode, C2 switches from active mode to sleep mode. When C1 switches from sleep mode to active mode, the voltage at Node n3 is higher than the voltage at Node n2.
D1 is not an open circuit and, at the same time or shortly before or shortly after C2 switches from sleep mode to active mode, C1 switches from active mode to sleep mode. When C2 switches from sleep mode to active mode, the voltage at Node n2 is higher than the voltage at Node n3.
D2 is not an open circuit and, at the same time or shortly before or shortly after C1 switches from sleep mode to active mode, C2 switches from active mode to sleep mode. When C1 switches from sleep mode to active mode, the voltage at Node n1 is higher than the voltage at Node n4.
D2 is not an open circuit and, at the same time or shortly before or shortly after C2 switches from sleep mode to active mode, C1 switches from active mode to sleep mode. When C2 switches from sleep mode to active mode, the voltage at Node n4 is higher than the voltage at Node n1.

For purposes of analyzing energy consumption in CMOS circuits, we note that charging a capacitive node through a direct connection to a V_{DD} rail takes energy from the V_{DD} rail. Energy dumped to the ground rail is energy that the capacitive node stored, and we need not account for it again. CR between “floating” capacitive nodes (with possibly different initial voltage levels) does not extract energy from the V_{DD} rail or dump energy to the ground rail. Instead, the resistance of the switch short circuiting the two capacitive nodes consumes some of the energy stored by the capacitors, while the remainder of the energy distributes between the capacitive nodes.

To calculate energy saving in a sleep-to-active transition, let C_{G} and C_{P} represent a total capacitance in the virtual ground and supply nodes, respectively. Assume that the sleep period is long enough to allow C_{G} to charge up to a voltage close to V_{DD} and C_{P} to discharge to a voltage close to 0. This assumption is valid for most circuits. If it is not, the voltages at C_{G} and C_{P} will be functions of the length of the sleep period. To go from sleep mode to active mode, instead of simply turning on sleep transistors, particular embodiments first allow CR between C_{G} and C_{P}. Particular embodiments allow CR between C_{G} and C_{P} by closing switch M at time t<tₐ₀ and opening switch M at time t=tₐ₀. Assuming ideal charge sharing between C_{G} and C_{P}, the common voltage value at nodes G and P after charge sharing can be calculated by equating a total charge in both capacitances before and after CR:

$${V}_{f} = α {V}_{DD} \\ α = \frac{{C}_{G}}{{C}_{G} + {C}_{P}} \qquad ( 1 )$$

The common voltage, V_{f}, at virtual ground and virtual supply at the end of charge sharing is αV_{DD}. After the completion of charge sharing, e.g., at time t=tₐ₀, particular embodiments open switch M and turn on the S_{N} and S_{P} sleep transistors, resulting in a path from virtual ground to actual ground through S_{N} that discharges C_{G} to 0 and a path from virtual V_{DD} to actual V_{DD} through S_{P} that charges C_{P} to V_{DD}. If the energy consumption in the switch itself is neglected, the total energy drawn from the power supply is a result of charging capacitance C_{P}, which particular embodiments obtain as follows:

$$\begin{matrix}{E}_{sleep \to active} = {C}_{P} {V}_{DD} Δ V \\ = {C}_{P} {V}_{DD} ( {V}_{DD} - {V}_{f} )\end{matrix} \qquad ( 2 )$$

Particular embodiments substitute V_{f} from Equation 1 to Equation 2 to obtain energy consumed during sleep-active transition:

$$\begin{matrix}{E}_{sleep \to active} = {C}_{P} {V}_{DD} ( {V}_{DD} - α {V}_{DD} ) \\ = ( 1 - α ) {C}_{P} {V}_{DD}^{2}\end{matrix} \qquad ( 3 )$$

As mentioned earlier, to go from active mode to sleep mode, instead of simply turning off the sleep transistors, particular embodiments carry out CR between C_{G} and C_{P} as soon as the circuit enters sleep mode. In other words, particular embodiments close switch M at t=tₛ₀, when the sleep transistors are off. The voltage values of the virtual ground and virtual V_{DD} nodes at t=tₛ₀ are 0 and V_{DD}, respectively. Assuming ideal charge sharing between C_{G} and C_{P}, particular embodiments calculate a common voltage value of nodes G and P after charge sharing by equating the total charge in both capacitances right before and after charge sharing:

$${V}_{f} = β {V}_{DD} \\ β = \frac{{C}_{P}}{{C}_{G} + {C}_{P}} \qquad ( 4 )$$

Based on the above equation, the common voltage value, V_{f}, of the virtual ground and virtual V_{DD} at the end of charge sharing is βV_{DD}. The CR is complete at t=tₐ₀, so particular embodiments open the switch. After opening the switch, a leakage path from the power supply to the virtual ground through logic block C₁ eventually causes C_{G} to charge up to V_{DD}. A leakage path from virtual supply to ground through logic block C₂ eventually causes C_{P} to completely discharge to ground. Again, if the power consumption in the switch is neglected, the total energy consumed is due to charging up the capacitance C_{G}; particular embodiments may calculate the energy consumption as follows:

$$\begin{matrix}{E}_{sleep \to active} = {C}_{G} {V}_{DD} Δ V \\ = {C}_{G} {V}_{DD} ( {V}_{DD} - {V}_{f} )\end{matrix} \qquad ( 5 )$$

Substituting V_{f} from Equation 4 into Equation 5, particular embodiments obtain:

$$\begin{matrix}{E}_{sleep \to active} = {C}_{G} {V}_{DD} ( {V}_{DD} - β {V}_{DD} ) \\ = ( 1 - β ) {C}_{G} {V}_{DD}^{2}\end{matrix} \qquad ( 6 )$$

Since α+β=1, total energy consumption will be:

$$\begin{matrix}{E}_{CRMTCMOS} = {E}_{active \to sleep} + {E}_{sleep \to active} \\ = α {C}_{G} {V}_{DD}^{2} + β {C}_{P} {V}_{DD}^{2}\end{matrix} \qquad ( 7 )$$

The term E_{CRMTCMOS} represents dynamic energy consumption during mode transition in the CR circuit.

Particular embodiments may calculate total energy consumption of a corresponding conventional MTCMOS circuit, e.g., when no CR is used using the following formula:

E_{MTCMOS}=C_{G}V_{DD}+C_{P}V_{DD}² (8)

From Equation 7 and Equation 8, and after substituting for α and β from Equation 1 and Equation 4, the ESR would be:

$$ESR ( X ) = \frac{{E}_{MTCMOS} - {E}_{CRMTCMOS}}{{E}_{MTCMOS}} = \frac{2 X}{{( 1 + X )}^{2}} \qquad ( 9 )$$

The term X=C_{G}/C_{P} represents a ratio of virtual ground capacitance to virtual V_{DD} capacitance. Particular embodiments obtain an optimum value of X maximizing ESR(X) by equating a derivative of ESR(X) to zero, which results in X=1 or C_{G}=C_{P}. In other words, to obtain a maximum energy saving, particular embodiments should have equal capacitances at virtual ground and virtual V_{DD}. Then the maximum energy saving is:

ESRₘₐₓ=ESR(X)|_{X=1}=½ (10)

Accordingly, particular embodiments may achieve a maximum energy saving of approximately 50% by using a CR method. However, considering the power needed to turn on and off the TG, the total saving ratio will likely be less than approximately 50%.

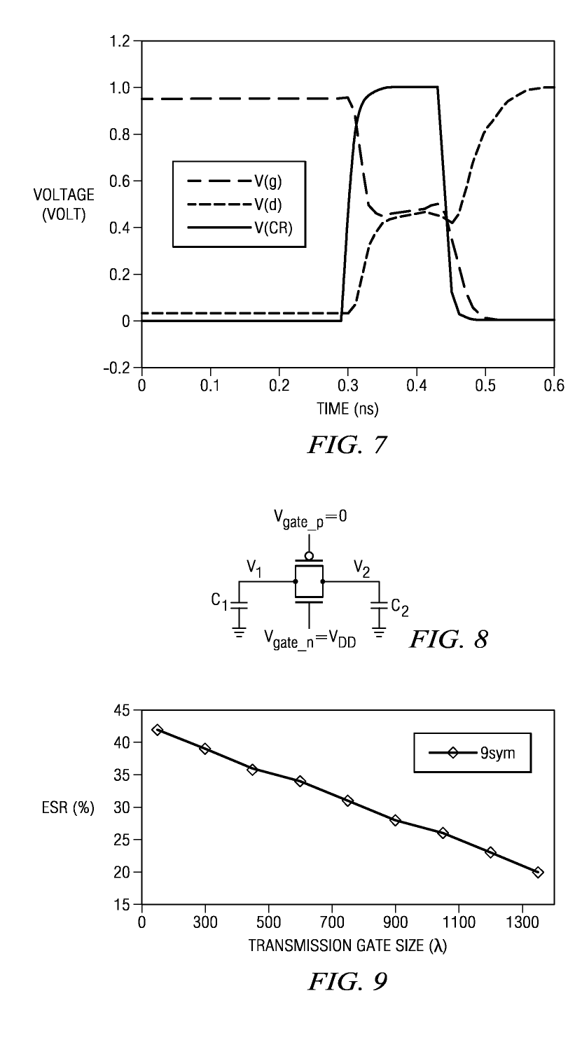

FIG. 7 illustrates example CR waveforms when CR occurs before transitioning from sleep to active mode for an inverter chain implemented in 70-nanometer CMOS technology. In the circuit, C_{G}=C_{P}. The FIGURE shows the virtual ground voltage, V_{G}, the virtual V_{DD} voltage, V_{P}, and the CR signal, V_{CR}.

In particular embodiments, the assumption that a virtual ground (virtual V_{DD}) node charges to a voltage close to V_{DD} (discharges to a voltage close to ground) during sleep mode is valid.

Particular embodiments base the equations above on the assumption of ideal CR between C_{G} and C_{P}. Under this scenario, we assume switching on and off the TG consumes approximately no energy. We also assume that the TG is on during the entire process of CR. However, because of dynamic power consumption at the TG and the possibility of having incomplete charge sharing, in particular embodiments, this may be an unsuitable assumption. Particular embodiments take into account effects of TG threshold voltage and sizing on the ESR and the wakeup time of the CR configuration.

Particular embodiments take into account effects of threshold voltages of NMOS and PMOS transistors of the TG on the energy saving and the delay of the circuit.

Consider the example charge sharing configuration in FIG. 8, where V₁ and V₂ are at V_{DD} and 0 initially. After the TG closes, the common node voltage is V_{f}. For complete charge sharing, the TG should stay on during the entire charge sharing process. To enable the TG to stay on during the entire charge sharing process, the absolute value of at least one of the threshold voltages of the NMOS and PMOS transistors of the TG should be relatively small. To achieve this, a common final voltage at virtual ground and virtual supply, V_{f}, should satisfy at least one of the following two inequalities:

$$\{ \begin{matrix} {V}_{t , n} \leq {V}_{DD} - {V}_{f} \\ or \\ \vert {V}_{t , p} \vert \leq {V}_{f}\end{matrix} \qquad ( 11 )$$

The terms V_{t,n} and V_{t,p} represent threshold voltages of NMOS and PMOS transistors in the TG accounting for body effect. Particular embodiments may obtain the value of V_{f} from Equation 1 for the active-to-sleep case and from Equation 4 for the sleep-to-active case. The inequalities in Equation 11 help ensure that at least one of the transistors in the TG remains on during the entire charge sharing process.

In the case of equal virtual node capacitances, C_{G}=C_{P}, complete charge sharing in both active-to-sleep and sleep-to-active cases results in a common final voltage value of V_{f}=V_{DD}/2, and Equation 11 simplifies to Min{V_{t,n},|V_{t,p}|}≦V_{DD}/2. (If Min{V_{t,n},|V_{t,p}|}>V_{DD}/2, CR will not complete and the ESR will be less than predicted.) Now, if V_{t,n}=|V_{t,p}|≦V_{DD}/2 particular embodiments may replace a TG with a pass transistor and still achieve full charge sharing.

Sizing of the TG also affects ESR as well as wakeup time of the circuit. In the case of the original configuration, e.g., no CR, we may define wakeup time as the time between the sleep transistors turning on and voltage at virtual ground (or virtual V_{DD}) reaching to within approximately 10%×V_{DD} of its final value. However, in a circuit that uses CR, we may define wakeup time as the time between the TG turning on and voltage at virtual ground (or virtual V_{DD}) reaching approximately 10%×V_{DD} of its final value after sleep transistors turn on. Particular embodiments take into account effects of dynamic power consumption by the TG on ideal ESR, as calculated above.

Consider a TG and its control signal. A CMOS inverter may produce the complement of the control signal. Assume a total input capacitance of Cg for the NMOS and PMOS transistors of the TG. In each active-sleep-active cycle, particular embodiments turn on the TG twice, once before turning the sleep transistors on and once after turning them off. Every time the TG turns on and off, C_{tg} charges and discharges. Particular embodiments turn off the TG after charge sharing completes. Therefore, particular embodiments may calculate dynamic energy consumption by the TG for one complete active-sleep-active cycle as follows:

E_{TG}=2C_{tg}V_{DD}² (12)

Therefore, particular embodiments may calculate actual ESR by subtracting the correction ratio E_{TG}/E_{MTCMOS} from the ideal ESR in Equation 9. Particular embodiments may calculate the correction ratio as follows:

$$\frac{{E}_{TG}}{{E}_{MTCMOS}} = \frac{2 {C}_{tg} {V}_{DD}^{2}}{( {C}_{G} + {C}_{P} ) {V}_{DD}^{2}} = \frac{2 {C}_{tg}}{{C}_{G} + {C}_{P}} \qquad ( 13 )$$

The correction ratio is proportional to the sizes of the transistors in the TG, since C_{tg} is proportional to the size of the TG. Because many gates are usually connected to virtual ground and virtual V_{DD}, C_{G}+C_{P} is usually significantly larger than C_{tg}. Thus, the correction ratio is usually a relatively small percentage, which tends to make actual ESR less than ideal ESR, e.g., approximately 50%, by only a few percentage points.

FIG. 9 illustrates example ESR versus total transistor width used in a TG. As seen, ESR decreases as TG size increases.

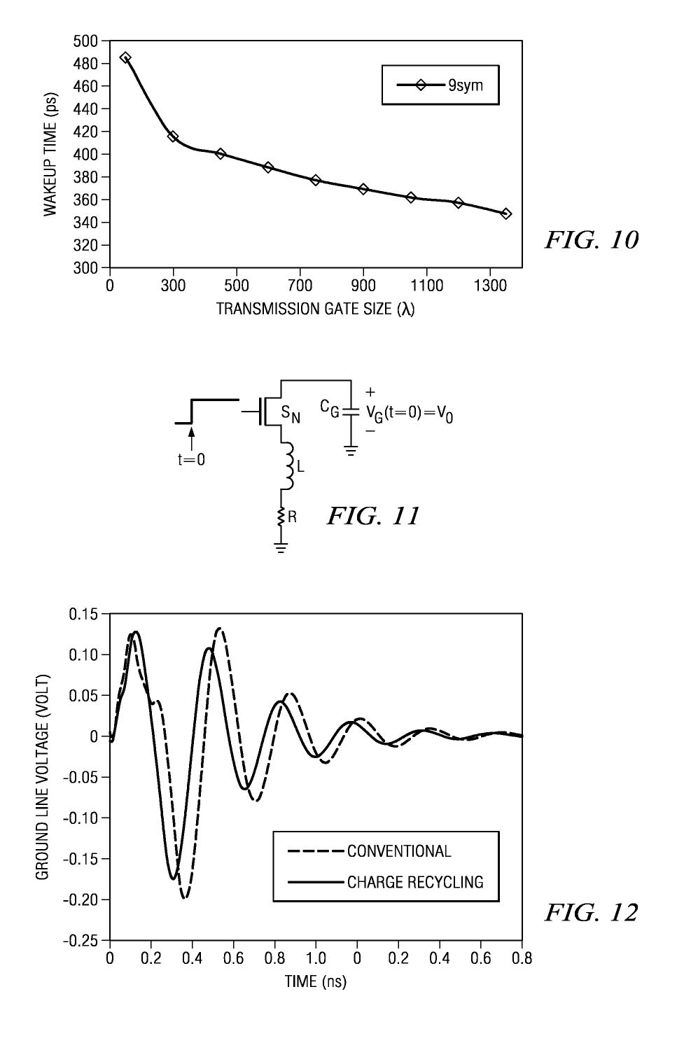

By changing TG size, particular embodiments may change the speed of charge sharing and, as a result, reduce or even minimize wakeup time. However, charge sharing only changes the virtual node voltages from their initial values to V_{f}. The sleep transistors perform the rest of the wakeup operation, and its duration depends on the sizes of the sleep transistors. Increasing TG size does not necessarily affect how fast the sleep transistors change the virtual node voltages from Vₜ to V_{DD} or ground, as the case may be. Therefore, we expect total wakeup time of the circuit to decrease when TG size increases, but it saturates at some point. FIG. 10 illustrates example circuit wakeup time versus total transistor width used in a TG. Although increasing TG size reduces wakeup time, it increases the correction ratio in Equation 13, thereby changing ESR of the circuit. In particular embodiments, there is a tradeoff between wakeup time and ESR.

Next, we consider leakage current and Ground Bounce (GB) in a CR MTCMOS configuration in particular embodiments.

Particular embodiments derive leakage current equations for both MTCMOS and CR MTCMOS circuits. Particular embodiments may express the leakage current of a metal oxide semiconductor (MOS) as follows:

$${I}_{leakage} = {μ}_{0} \frac{{ɛ}_{ox}}{{T}_{ox}} \frac{W}{L} {v}_{T}^{2} {e}^{1.8} {e}^{\frac{\vert {V}_{gs} - {V}_{th} \vert}{{Sv}_{T}}} ( 1 - {e}^{- \frac{\vert {V}_{ds} \vert}{{v}_{T}}} ) \qquad ( 14 )$$

The terms V_{gs} and V_{ds} represent gate-source and drain-source voltages of the transistor and W/L represents the width-to-length ratio of the transistor. In sleep mode, all sleep and CR transistors are off, e.g., they all have V_{gs}=0. Here, V_{ds} for each sleep or CR transistor is an absolute voltage difference between virtual ground and virtual V_{DD} nodes in sleep mode, which approximately equals V_{DD}, as discussed above. From Equation 14, we may ignore the dependence of the subthreshold leakage current of the transistor on V_{ds}, since V_{ds}≧75 mV. Two leakage current components correspond to the two leakage paths in a conventional MTCMOS circuit: the NMOS sleep transistor leakage current I_{Ln} and the PMOS sleep transistor leakage current I_{Lp}. Assuming the widths of NMOS and PMOS sleep transistors are Wₙ and Wₚ, respectively, particular embodiments may express I_{Ln} and I_{Lp} as:

$$\begin{matrix}{I}_{Ln} = {μ}_{n} \frac{{ɛ}_{ox}}{{T}_{ox}} \frac{{W}_{n}}{L} {v}_{T}^{2} {e}^{1.8} {e}^{\frac{- {V}_{tH}}{{Sv}_{T}}} \\ {I}_{Lp} = {μ}_{p} \frac{{ɛ}_{ox}}{{T}_{ox}} \frac{{W}_{p}}{L} {v}_{T}^{2} {e}^{1.8} {e}^{\frac{- {V}_{tH}}{{Sv}_{T}}}\end{matrix} \qquad ( 15 )$$

The term V_{tH} represents the threshold voltage of the sleep transistors. The total leakage current of the MTCMOS circuit is the sum of I_{Ln} and I_{Lp}:

$${I}_{leakage}^{MTCMOS} = ( {μ}_{n} {W}_{n} + {μ}_{p} {W}_{p} ) \frac{{ɛ}_{ox}}{{LT}_{ox}} {v}_{T}^{2} {e}^{1.8} {e}^{\frac{- {V}_{tH}}{{Sv}_{T}}} \qquad ( 16 )$$

However, for CR MTCMOS, there is an additional leakage component, I_{Lcr}, due to the CR transistor. For purposes of this section, assume CR uses a single NMOS transistor with the width W_{cr} instead of a TG. Using Equation 14, particular embodiments may express I_{Lcr} as:

$${I}_{Lcr} = {μ}_{n} \frac{{ɛ}_{ox}}{{T}_{ox}} \frac{{W}_{cr}}{L} {v}_{T}^{2} {e}^{1.8} {e}^{\frac{- {V}_{tH}}{{Sv}_{T}}} \qquad ( 17 )$$

Using Equation 16 and Equation 17, particular embodiments may express the ratio of leakage current in MTCMOS and CR MTCMOS as:

$$\begin{matrix}\frac{{I}_{leakage}^{CRMTCMOS}}{{I}_{leakage}^{MTCMOS}} = \frac{{μ}_{n} {W}_{n} + {μ}_{n} {W}_{cr} + {μ}_{p} {W}_{p}}{{μ}_{n} {W}_{n} + {μ}_{p} {W}_{p}} \\ = 1 + \frac{{W}_{cr}}{{W}_{n} + ( {μ}_{p} / {μ}_{n} ) {W}_{p}}\end{matrix} \qquad ( 18 )$$

Assuming μₙ=2μₚ and Wₙ=0.5 Wₚ:

$$\frac{{I}_{leakage}^{CRMTCMOS}}{{I}_{leakage}^{MTCMOS}} = 1 + \frac{{W}_{cr}}{2 {W}_{n}} \qquad ( 19 )$$

Since the CR transistor is usually significantly smaller than the sleep transistors, the leakage increase ratio in Equation 19 may be small when compared with the power saving achieved by CR.

Ground and power line bounces are important design considerations when using power gating. GB or power bounce may occur in power gating structures at a sleep-to-active transition edge. In particular embodiments, CR may affect GB. Consider the circuit in FIG. 11. Large current flows to ground after the sleep transistor turns on at the end of a sleep period. Particular embodiments adopt a simple RL model for purposes of GB analysis. Because of the large di/dt at turn-on time, a large voltage, e.g., Ldi/dt, appears across the inductance.

FIG. 11 shows a virtual ground capacitance C_{G} connected to an RL circuit via a sleep transistor S_{N}. The RL circuit models pin-package parasitics of the integrated circuit (IC). The sleep transistor turns on at t=0 when the initial voltage of C_{G} is V₀, e.g., V_{G}(t=0)=V₀. The GB positive peak occurs when S_{N} is in the saturation region. Although the peak value does not depend on V₀, the peak value is a function of R, L, C_{G}, V_{Tn} and V_{DD}. Therefore, we would expect the proposed CR technique (which changes V₀ from V_{DD} to V_{f}) not to change the GB positive peak. However, both the GB negative peak and the settling time of the GB are functions of V₀. Moreover, both quantities decrease if V₀ is reduced. Therefore, both the negative peak value and the settling time of the GB voltage should decrease for the CR MTCMOS circuit.

In particular embodiments, the amount of improvement in the negative peak and the settling time depend on the relative values of L, C_{G}, R, V_{DD}, and the sleep transistor parameters. FIG. 12 compares GB waveforms for conventional and CR power gating structures in an inverter chain using 70-nanometer CMOS technology. The positive peak value is approximately the same in both cases. However, the negative peak value and the settling time are smaller for the CR MTCMOS structure.

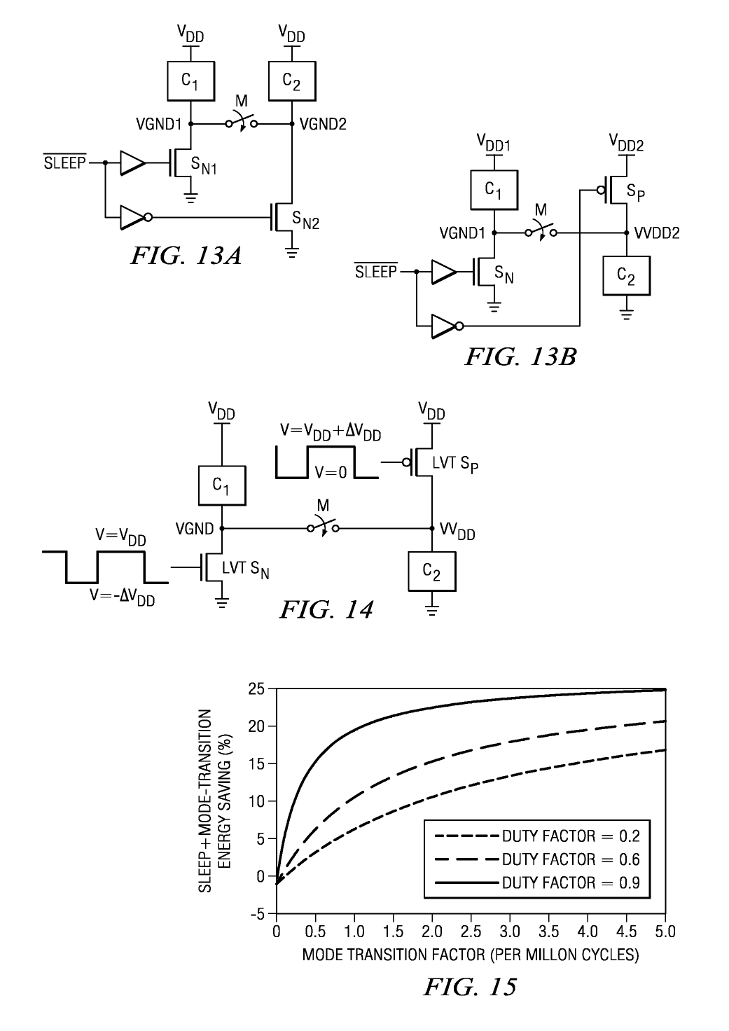

Particular embodiments use one or more of three variations of CR for MTCMOS circuits. Above, we describe and illustrate CR using both NMOS and PMOS sleep transistors and applying CR between virtual ground and virtual V_{DD} nodes. It is possible to implement CR between two virtual grounds or between two virtual V_{DD} nodes. For example, FIG. 6 illustrates such CR in a general case. FIG. 13a illustrates such CR in a special case.

Consider FIG. 13a, where two circuit blocks C₁ and C₂ use the same type of sleep transistors, e.g., NMOS transistors. Suppose C₁ and C₂ work in “orthogonal” modes, e.g., when C₁ is in active mode, C₂ is in sleep mode, and vice versa. For example, C₁ and C₂ may be integer and floating-point arithmetic blocks of a processor. When the integer arithmetic block is used, the floating-point block is idle, and vice versa. Particular embodiments may perform CR between virtual ground nodes of blocks C₁ and C₂, indicated by VGND₁ and VGND₂, respectively.

First, assume C₁ is in active mode and C₂ is in sleep mode. Voltages of VGND₁ and VGND₂ are 0 and V_{DD}, respectively. When C₁ switches to sleep mode, C₂ switches to active mode and the voltages of VGND₁ and VGND₂ change to V_{DD} and 0 after some time, respectively. Therefore, the CR may occur between the VGND₁ and VGND₂ nodes to save energy wasted during mode transition.

In particular embodiments, energy consumption for the MTCMOS and CR MTCMOS circuits in a full active-sleep-active cycle are as follows:

E_{MTCMOS}=(C_{G}_{₁}+C_{G}_{₂})V_{DD}²

E_{CR MTCMOS}=C_{G}_{₁}V_{DD}ΔV₁+C_{G}_{₂}V_{DD}ΔV₂ (20)

The terms ΔV₁ and ΔV₂ are voltage differences between a final CR voltage value and supply voltage values of the two blocks, and particular embodiments may calculate them as follows:

$$\begin{matrix}Δ {V}_{1} = {V}_{DD} - \frac{{C}_{{G}_{2}}}{{C}_{{G}_{1}} + {C}_{{G}_{2}}} {V}_{DD} \\ Δ {V}_{2} = {V}_{DD} - \frac{{C}_{{G}_{1}}}{{C}_{{G}_{1}} + {C}_{{G}_{2}}} {V}_{DD}\end{matrix} \qquad ( 21 )$$

Substituting ΔV₁ and ΔV₂ from Equation 21 into Equation 20, particular embodiments may calculate ESR as follows:

$$\frac{{E}_{CRMTCMOS}}{{E}_{MTCMOS}} = \frac{{C}_{{G}_{1}}^{2} + {C}_{{G}_{2}}^{2}}{{( {C}_{{G}_{1}} + {C}_{{G}_{2}} )}^{2}} \qquad ( 22 )$$

In particular embodiments, such results are similar to ESR from regular CR. Particular embodiments achieve a maximum energy saving of 50% when C_{G1}=C_{G2}. Similarly, particular embodiments may apply CR between virtual V_{DD} nodes of two blocks that use PMOS sleep transistors.

Consider FIG. 13b, where two circuit blocks C₁ and C₂ use two different power supply levels, V_{DD1} and V_{DD2}, respectively. If C₁ and C₂ use different types of sleep transistors (e.g. C₁ uses an NMOS while C² uses a PMOS sleep transistor) and C₁ and C₂ are always in the same mode of operation (e.g. they are both in sleep mode or they are both in active mode) particular embodiments may apply CR between the virtual ground of C₁, VGND₁, and the virtual supply of C₂, VV_{DD2}.

In this case, particular embodiments may express energy consumption for the MTCMOS and CR MTCMOS circuits as follows:

E_{MTCMOS}=C_{G}_{₁}V_{DD}_{₁}²+C_{P}_{₂}V_{DD}_{₂}²

E_{CR MTCMOS}=C_{G}_{₁}V_{DD}_{₁}ΔV₁+C_{P}_{₂}V_{DD}_{₂}ΔV₂ (23)

The terms ΔV₁ and ΔV₂ represent voltage differences between a final CR voltage value and supply voltage values of the two blocks, and particular embodiments may calculate them as follows:

$$\begin{matrix}Δ {V}_{1} = {V}_{{DD}_{1}} - \frac{{C}_{{P}_{2}}}{{C}_{{G}_{1}} + {C}_{{P}_{2}}} {V}_{{DD}_{2}} \\ Δ {V}_{2} = {V}_{{DD}_{2}} - \frac{{C}_{{G}_{1}}}{{C}_{{G}_{1}} + {C}_{{P}_{2}}} {V}_{{DD}_{1}}\end{matrix} \qquad ( 24 )$$

Substituting ΔV₁ and ΔV₂ from Equation 24 into Equation 23, particular embodiments may calculate ESR as follows:

$$\begin{matrix}ESR = \frac{{E}_{MTCMOS} - {E}_{CRMTCMOS}}{{E}_{MTCMOS}} \\ = \frac{2 {C}_{G 1} {C}_{P 2} {V}_{DD 1} {V}_{DD 2}}{( {C}_{G 1} + {C}_{P 2} ) ( {C}_{G 1} {V}_{DD 1}^{2} + {C}_{P 2} {V}_{DD 2}^{2} )}\end{matrix} \qquad ( 25 )$$

From Equation 25, ESR in this case depends not only on capacitance values in the virtual rails, but also on both supply voltage values. If V_{DD1}=V_{DD2}, Equation 25 reduces to Equation 9.

Turning on HVT devices is often difficult in sub 1 V CMOS. In 45-nanometer technology, a best corner V_{DD} may be approximately 0.9V while standard threshold voltage SVT may be approximately 0.5V. For acceptable leakage saving, a high threshold voltage should be at least 0.65V, which leaves a margin of only 0.25V for gate-source voltage (0.65<V_{GS}<0.9 V) of a turned on NMOS sleep transistor when using MTCMOS. Therefore, high threshold voltage (HVT) sleep transistors are usually too slow and hard to turn on in sub 1V CMOS.

SCCMOS circuits may solve this problem by using a low threshold voltage (LVT) device for cutting off ground or V_{DD}. Instead of using HVT devices for leakage reduction, SCCMOS circuits overdrive the LVT PMOS sleep transistors by applying a positive overdrive voltage of αV_{DD} in excess of V_{DD} to their gate terminals. Similarly, they under drive the LVT NMOS sleep transistors by applying a negative voltage of −ΔV_{DD} to their gate terminals. SCCMOS circuits achieve similar leakage reduction to corresponding MTCMOS circuits with shorter wakeup times due to the use of LVT transistors.

Similar to MTCMOS, SCCMOS circuits tend to suffer from wasteful mode transition energy consumption. Both NMOS and PMOS sleep transistors may cut off power or ground from the gates in a circuit. During standby mode, due to leakage, a virtual ground node will charge to a value close to V_{DD} while a virtual V_{DD} node will discharge to a voltage close to ground. The opposite situation occurs in active mode. Consequently, particular embodiments may apply CR to SCCMOS circuits to save mode transition energy as applied to MTCMOS circuits. FIG. 14 illustrates an example configuration of a circuit used for CR SCCMOS.

Particular embodiments divide each circuit into two subcircuits, one using an NMOS sleep transistor and the other using a PMOS sleep transistor for power gating. Particular embodiments choose subcircuits to make total capacitance values in the virtual nodes approximately equal to each other. Particular embodiment may apply this technique to the example CR configurations in FIGS. 5 and 6. Moreover, particular embodiments may use SCCMOS CR transistors.

Particular embodiments first generate an MTCMOS version of the circuit as follows. A single NMOS sleep transistor is used to cut off ground from virtual ground during sleep time. The size of this sleep transistor is set for a voltage drop of no more than approximately 5% of V_{DD} across its R_{DS}(ON) when the circuit is active, which may limit the performance penalty of the power gating structure. One or more known optimizations may be used to formulate and solve this problem. In particular embodiments, we assume at most 20% of the logic gates in the circuit have a simultaneous high-to-low output transition in any given cycle, each transition contributing an average of ΔI_{avg} current to total current flowing through the ON sleep transistor. Therefore:

$$\begin{matrix}{R}_{ds , n} ( ON ) = \frac{Δ V}{I} = \frac{0.05 {V}_{DD}}{\frac{N}{5} Δ {I}_{avg}} = \frac{{V}_{DD}}{4 N Δ {I}_{avg}} \\ {( \frac{W}{L} )}_{n} = \frac{1}{{R}_{ds , n} ( ON ) {μ}_{n} {C}_{ox} ( {V}_{DD} - {V}_{tH , n} )}\end{matrix} \qquad ( 26 )$$

Next, particular embodiments generate a version of the circuit benchmarks that uses both NMOS and PMOS sleep transistors. Particular embodiments partition circuit C into two blocks, C1 and C2, where C1 uses an NMOS sleep transistor and C2 uses a PMOS sleep transistor. Particular embodiments carry out the partitioning to make total capacitance at the virtual ground node of C1 equal to total capacitance at the virtual voltage node of C2. Particular embodiments may determine sizing for the NMOS and PMOS sleep transistors for each circuit block as done in the ST MTCMOS case which uses a single type of sleep transistor, accounting for differences between hole and electron mobility. Where appropriate, we refer to this version as NP MTCMOS, because it uses both types of sleep transistors, but does not perform CR.

Particular embodiments incorporate CR into NP MTCMOS by using an appropriately sized TG as a switch between the virtual ground of C1 and the virtual V_{DD} of C2. Particular embodiments may select the size of the TG to cause the wakeup times of the NP MTCMOS and the CR MTCMOS circuits to be approximately equal. Particular embodiments perform the optimization by measuring the wakeup time of the NP MTCMOS circuit and sweeping the TG size (using SPICE) while monitoring the wakeup time of the CR MTCMOS circuit.

Finally, particular embodiments generate CR SCCMOS by enabling charge sharing with an appropriately sized TG. Similar to the CR MTCMOS case, particular embodiments determine the size of the TG through SPICE simulation, with a goal of equating the wakeup times of the NP SCCMOS and CR SCCMOS circuits.

Particular embodiments determine the size of the TG through SPICE simulation, with a goal of maximizing the energy savings achieved by CR in CR SCCMOS circuits.

In particular embodiments, the value of the overdrive voltage for a PMOS super cutoff switch in the SCCMOS circuit is set to the threshold voltage difference between the HVT and LVT PMOS devices in the MTCMOS circuit. Similarly, the value of the underdrive voltage for an NMOS switch in the SCCMOS circuit is set to the threshold voltage difference between the HVT and LVT NMOS devices in the MTCMOS circuit.

Reducing ground and power rail bounces are often important issues in the design of MTCMOS circuits. As described and illustrated above, in particular embodiments, CR may reduce the ground (power) bounce of an MTCMOS circuit.

Next, we compare ST MTCMOS and CR MTCMOS circuits in terms of total energy consumption.

Particular embodiments may express total energy consumptions in ST MTCMOS and CR MTCMOS circuits as a summation of their corresponding active and sleep mode energy consumption plus energy consumption due to mode transition in the circuits:

Eₜₒₜₐₗ^{ST-MTCMOS}=E_{active}^{ST-MTCMOS}+Eₛₗₑₑₚ^{ST-MTCMOS}+Eₘₜ^{ST-MTCMOS}

Eₜₒₜₐₗ^{CR-MTCMOS}=E_{active}^{CR-MTCMOS}+Eₛₗₑₑₚ^{CR-MTCMOS}+Eₘₜ^{CR-MTCMOS} (27)

Active-mode energy consumption for both cases includes two parts: a dynamic component and a static (leakage) component. Since the ON resistance of the sleep transistor in active mode is nonzero, both active-mode energy components are slightly different in the ST MTCMOS and CR MTCMOS circuits. However, particular embodiments ignore this secondary effect. Therefore:

E_{active}^{ST-MTCMOS}=E_{active}^{CR-MTCMOS}=(c_{sw}V_{DD}²f_{clk}+IₗₐV_{DD})t_{active} (28)

The term c_{sw} represents the average switched capacitance for the circuit in each clock cycle. The term f_{clk} represents the clock frequency. The term Iₗₐ represents average active leakage current in the circuit. The term t_{active} represents a total time the circuit is active. Particular embodiments perform energy calculations over N_{clk} clock cycles and express as follows:

t_{active}=αN_{clk}T_{clk}

tₛₗₑₑₚ=(1−α)N_{clk}T_{clk} (29)

The term T_{clk}=1f_{clk} represents the clock period, and α represents a duty factor which particular embodiments define as a percentage of total time that the circuit is active.

Particular embodiments may express sleep-mode energy consumption for the two circuits as follows:

$${E}_{sleep}^{ST - MTCMOS} = {I}_{{ls}_{n}}^{ST} {V}_{DD} {t}_{sleep} \\ {E}_{sleep}^{CR - MTCMOS} = ( {I}_{{l}_{{s}_{n}}}^{CR} + {I}_{{l}_{{s}_{p}}}^{CR} + {I}_{lscr}^{CR} ) {V}_{DD} {t}_{sleep} \qquad ( 30 )$$

The term Iₗₛ_{ₙ}^{ST} represents leakage current through the sleep transistor in the ST MTCMOS circuit during sleep mode. The terms Iₗₛ_{ₙ}^{CR}, and Iₗₛ_{ₚ}^{CR} represents leakage currents through the NMOS and PMOS sleep transistors and the CR transistors in the CR MTCMOS circuit during sleep mode, respectively. Typically, leakage current through sleep transistors in both cases are on the same order. However, since the TG is smaller than the sleep transistors (usually less than one tenth the size of the sleep transistors) Iₗₛ_{_{cr}}^{CR} in Equation 30 is much smaller than (usually less than one tenth of) Iₗₛ_{ₙ}^{CR}+Iₗₛ_{ₚ}^{CR}.

Particular embodiments may calculate the mode-transition energy consumption for two circuits as follows:

Eₘₜ^{ST-MTCMOS}=(cₛₗₚ_{ₛₜ}+c_{G}_{ₛₜ})V_{DD}²βN_{clk}

Eₘₜ^{CR-MTCMOS}=(cₛₗₚ_{_{cr}}0.5(c_{G}_{_{cr}}+c_{P}_{_{cr}}))V_{DD}²βN_{clk} (31)

The terms cₛₗₚ_{ₛₜ} and cₛₗₚ_{_{cr}} represent total sleep transistor input capacitance in the ST MTCMOS and CR MTCOMS circuits, respectively, and c_{G}_{ₛₜ} represents total virtual ground capacitance in the ST MTCMOS circuit. The terms c_{G}_{_{cr}} and c_{P}_{_{cr}} represents total virtual ground and virtual V_{DD} capacitances in the CR MTCMOS circuit, respectively. β represents a mode transition factor, e.g., a percentage of clock cycles during which a mode transition occurs.

From Equation 28, in particular embodiments, active mode energy consumption is almost the same for both circuits, which means that CR does not influence active mode energy consumption. Therefore, particular embodiments do not consider the active mode energy consumption component of Equation 27 for the remainder. Therefore, particular embodiments may rewrite Equation 27 as follows:

E_{slp,mt}^{ST-MTCMOS}=Eₛₗₑₑₚ^{ST-MTCMOS}+Eₘₜ^{ST-MTCMOS}

E_{slp,mt}^{CR-MTCMOS}=Eₛₗₑₑₚ^{CR-MTCMOS}+Eₘₜ^{CR-MTCMOS} (32)

Substituting Equation 29, Equation 30, and Equation 31 into Equation 32, and ignoring terms related to the sleep transistors, particular embodiments obtain:

$$\begin{matrix}{E}_{slp , mt}^{ST - MTCMOS} = ( {I}_{{ls}_{n}}^{ST} {V}_{DD} ( 1 - α ) {T}_{clk} + {c}_{{G}_{st}} {V}_{DD}^{2} β ) {N}_{clk} \\ {E}_{slp , mt}^{CR - MTCMOS} = ( ( {I}_{{ls}_{n}}^{CR} + {I}_{{ls}_{p}}^{CR} + {I}_{lcr}^{CR} ) {V}_{DD} ( 1 - α ) {T}_{clk} + \frac{1}{2} ( {c}_{{G}_{cr}} + {c}_{{P}_{cr}} ) {V}_{DD}^{2} β ) {N}_{clk} & ( 33 )\end{matrix}$$

FIG. 15 shows a percentage of total energy saving of CR MTCMOS over ST MTCMOS as a function of mode-transition frequency for three different duty factor values. As the mode transition factor β increases, the percentage of energy saving increases for each case. CR saves energy during mode transition only. As the duty factor α increases, the total sleep time decreases and the total saving increases. We may see this in FIG. 15 by looking at energy saving plots for different activity factors. For large values of α (e.g. 0.9) and β, sleep plus mode transition ESR will approximately equal mode-transition ESR.

Particular embodiments apply CR to MTCMOS and SCCMOS circuits. By applying CR to an MTCMOS or SCCMOS circuit, particular embodiments may save up to approximately 43% of energy wasted during mode transition, while maintaining a wakeup time of the original MTCMOS or SCCMOS circuit. Particular embodiments may reduce peak voltage and settling time of GB occurring while the circuit wakes up. In particular embodiments, since CR transistors are smaller than sleep transistors, leakage increase due to an additional sneak path (as described and illustrated above) is usually relatively small.

The present disclosure encompasses all changes, substitutions, variations, alterations, and modifications to the example embodiments described herein that a person having ordinary skill in the art would comprehend. Similarly, where appropriate, the appended claims encompass all changes, substitutions, variations, alterations, and modifications to the example embodiments described herein that a person having ordinary skill in the art would comprehend.

We claim:

1. A circuit comprising:
a first circuit block connected to ground via a first sleep transistor;
a first virtual ground node between the first circuit block and the first sleep transistor;
a second circuit block connected to ground via a second sleep transistor;
a second virtual ground node between the second circuit block and the second sleep transistor; and
a transmission gate (TG) or a pass transistor connecting the first virtual ground node to the second virtual ground node to enable charge recycling between the first circuit block and the second circuit block during transitions by the first circuit block from active mode to sleep mode and the second circuit block from sleep mode to active mode or vice versa.

2. The circuit of claim 1, wherein the TG comprises an n-channel metal-oxide-semiconductor (NMOS) transistor and a p-channel metal-oxide-semiconductor (PMOS) transistor, a source of the NMOS transistor being connected to a drain of the PMOS transistor, a drain of the NMOS transistor being connected to a source of the PMOS transistor.

3. The circuit of claim 1, wherein a size of the TG or the pass transistor maintains or reduces a wake-up time of the circuit.

4. The circuit of claim 1, wherein placement and sizing of the TG or pass transistor takes into account a wake-up delay, energy consumption due to mode transition, or both.

5. The circuit of claim 1, wherein placement and sizing of the TG or pass transistor takes into account ground bounce (GB) during transitions by the circuit from sleep mode to active mode.

6. A method comprising:
switching a circuit from sleep mode to active mode, the circuit comprising a first circuit block connected to ground via a first sleep transistor, a first virtual ground node between the first circuit block and the first sleep transistor, a second circuit block connected to ground via a second sleep transistor, a second virtual ground node between the second circuit block and the second sleep transistor, and a transmission gate (TG) or a pass transistor connecting the first virtual ground node to the second virtual ground node to enable charge recycling between the first circuit block and the second circuit block during transitions by the first circuit block from active mode to sleep mode and the second circuit block from sleep mode to active mode or vice versa, the switch from sleep mode to active mode comprising:
turning on the TG or the pass transistor;
turning off the TG or the pass transistor after a predetermined period of time has lapsed; and
turning on the first and second sleep transistors after turning off the TG or the pass transistor; and
switching the circuit from active mode to sleep mode, the switch from active mode to sleep mode comprising:
turning off the first and second sleep transistors;
turning on the TG or the pass transistor after turning off the sleep transistors; and
turning off the TG or the pass transistor after a predetermined period of time has lapsed.

7. The method of claim 6, wherein the TG comprises an n-channel metal-oxide-semiconductor (NMOS) transistor and a p-channel metal-oxide-semiconductor (PMOS) transistor, a source of the NMOS transistor being connected to a drain of the PMOS transistor, a drain of the NMOS transistor being connected to a source of the PMOS transistor.

8. The method of claim 6, wherein a size of the TG or the pass transistor maintains or reduces a wake-up time of the circuit.

9. The method of claim 6, wherein placement and sizing of the TG or pass transistor takes into account a wake-up delay, energy consumption due to mode transition, or both.

10. The method of claim 6, wherein placement and sizing of the TG or pass transistor takes into account ground bounce (GB) during transitions by the circuit from sleep mode to active mode.

11. A circuit comprising:
a first circuit block connected to a power supply via a first sleep transistor;
a first virtual supply node between the first circuit block and the first sleep transistor;
a second circuit block connected to the power supply via a second sleep transistor;
a second virtual supply node between the second circuit block and the second sleep transistor; and
a transmission gate (TG) or a pass transistor connecting the first virtual supply node to the second virtual supply node to enable charge recycling between the first circuit block and the second circuit block during transitions by the first circuit block from active mode to sleep mode and the second circuit block from sleep mode to active mode or vice versa.

12. A method comprising:
switching a circuit from sleep mode to active mode, the circuit comprising a first circuit block connected to a power supply via a first sleep transistor, a first virtual supply node between the first circuit block and the first sleep transistor, a second circuit block connected to the power supply via a second sleep transistor, a second virtual supply node between the second circuit block and the second sleep transistor, and a transmission gate (TG) or a pass transistor connecting the first virtual supply node to the second virtual ground node to enable charge recycling between the first circuit block and the second circuit block during transitions by the first circuit block from active mode to sleep mode and the second circuit block from sleep mode to active mode or vice versa, the switch from sleep mode to active mode comprising:
turning on the TG or the pass transistor;
turning off the TG or the pass transistor after a predetermined period of time has lapsed; and
turning on the first and second sleep transistors after turning off the TG or the pass transistor; and
switching the circuit from active mode to sleep mode, the switch from active mode to sleep mode comprising:
turning off the first and second sleep transistors;
turning on the TG or the pass transistor after turning off the sleep transistors; and
turning off the TG or the pass transistor after a predetermined period of time has lapsed.

13. A circuit comprising:
a first circuit block connected to ground via a first sleep transistor;
a virtual ground node between the first circuit block and the first sleep transistor;
a second circuit block connected to a power supply via a second sleep transistor, the first and second circuits blocks having different power supply levels;
a virtual supply node between the second circuit block and the second sleep transistor; and
a transmission gate (TG) or a pass transistor connecting the virtual ground node to the virtual supply node to enable charge recycling between the first circuit block and the second circuit block during transitions by the circuit from active mode to sleep mode and from sleep mode to active mode.

14. The circuit of claim 13, wherein the first sleep transistor is an n-channel metal-oxide-semiconductor (NMOS) transistor and the second sleep transistor is a p-channel metal-oxide-semiconductor (PMOS) transistor

15. The circuit of claim 13, wherein the TG comprises an n-channel metal-oxide-semiconductor (NMOS) transistor and a p-channel metal-oxide-semiconductor (PMOS) transistor, a source of the NMOS transistor being connected to a drain of the PMOS transistor, a drain of the NMOS transistor being connected to a source of the PMOS transistor.

16. The circuit of claim 13, wherein a size of the TG or the pass transistor maintains or reduces a wake-up time of the circuit.

17. The circuit of claim 13, wherein placement and sizing of the TG or pass transistor takes into account a wake-up delay, energy consumption due to mode transition, or both.

18. The circuit of claim 13, wherein placement and sizing of the TG or pass transistor takes into account ground bounce (GB) during transitions by the circuit from sleep mode to active mode.

19. The circuit of claim 13, comprising a plurality of TGs or pass transistors.

20. A method comprising:
switching a circuit from sleep mode to active mode, the circuit comprising a first circuit block connected to ground via a first sleep transistor, a virtual ground node between the first circuit block and the first sleep transistor, a second circuit block connected to a power supply via a second sleep transistor, a virtual supply node between the second circuit block and the second sleep transistor, the first and second circuits blocks having different power supply levels, and a transmission gate (TG) or a pass transistor connecting the first virtual ground node to the second virtual ground node to enable charge recycling between the first circuit block and the second circuit block during transitions by the circuit from active mode to sleep mode and vice versa, the switch from sleep mode to active mode comprising:
turning on the TG or the pass transistor;
turning off the TG or the pass transistor after a predetermined period of time has lapsed; and
turning on the first and second sleep transistors after turning off the TG or the pass transistor; and
switching the circuit from active mode to sleep mode, the switch from active mode to sleep mode comprising:
turning off the first and second sleep transistors;
turning on the TG or the pass transistor after turning off the sleep transistors; and
turning off the TG or the pass transistor after a predetermined period of time has lapsed.

21. The method of claim 20, wherein the first sleep transistor is an n-channel metal-oxide-semiconductor (NMOS) transistor and the second sleep transistor is a p-channel metal-oxide-semiconductor (PMOS) transistor

22. The method of claim 20, wherein the TG comprises an n-channel metal-oxide-semiconductor (NMOS) transistor and a p-channel metal-oxide-semiconductor (PMOS) transistor, a source of the NMOS transistor being connected to a drain of the PMOS transistor, a drain of the NMOS transistor being connected to a source of the PMOS transistor.

23. The method of claim 20, wherein a size of the TG or the pass transistor maintains or reduces a wake-up time of the circuit.

24. The method of claim 20, wherein placement and sizing of the TG or pass transistor takes into account a wake-up delay, energy consumption due to mode transition, or both.

25. The method of claim 20, wherein placement and sizing of the TG or pass transistor takes into account ground bounce (GB) during transitions by the circuit from sleep mode to active mode.

26. The method of claim 20, wherein the circuit comprises a plurality of TGs or pass transistors.

27. A circuit comprising:
a first circuit block connected to ground via a first low threshold voltage (LVT) sleep transistor, the first LVT sleep transistor having a positive overdrive voltage at its gate terminal;
a virtual ground node between the first circuit block and the first LVT sleep transistor;
a second circuit block connected to a power supply via a second LVT sleep transistor, the second LVT sleep transistor having a positive overdrive voltage at its gate terminal;
a virtual supply node between the second circuit block and the second LVT sleep transistor; and
a transmission gate (TG) or a pass transistor connecting the virtual ground node to the virtual supply node to enable charge recycling between the first circuit block and the second circuit block during transitions by the circuit from active mode to sleep mode and from sleep mode to active mode.

28. The circuit of claim 27, wherein the first sleep transistor is an n-channel metal-oxide-semiconductor (NMOS) transistor and the second sleep transistor is a p-channel metal-oxide-semiconductor (PMOS) transistor

29. The circuit of claim 27, wherein the TG comprises an n-channel metal-oxide-semiconductor (NMOS) transistor and a p-channel metal-oxide-semiconductor (PMOS) transistor, a source of the NMOS transistor being connected to a drain of the PMOS transistor, a drain of the NMOS transistor being connected to a source of the PMOS transistor.

30. The circuit of claim 27, wherein a size of the TG or the pass transistor maintains or reduces a wake-up time of the circuit.

31. The circuit of claim 27, wherein placement and sizing of the TG or pass transistor takes into account a wake-up delay, energy consumption due to mode transition, or both.

32. The circuit of claim 27, wherein placement and sizing of the TG or pass transistor takes into account ground bounce (GB) during transitions by the circuit from sleep mode to active mode.

33. The circuit of claim 27, comprising a plurality of TGs or pass transistors.

34. A method comprising:
switching a circuit from sleep mode to active mode, the circuit comprising a first circuit block connected to ground via a first low threshold voltage (LVT) sleep transistor having a positive overdrive voltage at its gate terminal, a virtual ground node between the first circuit block and the first sleep transistor, a second circuit block connected to a power supply via a second LVT sleep transistor having a positive overdrive voltage at its gate terminal, a virtual supply node between the second circuit block and the second sleep transistor, the first and second circuits blocks having different power supply levels, and a transmission gate (TG) or a pass transistor connecting the first virtual ground node to the second virtual ground node to enable charge recycling between the first circuit block and the second circuit block during transitions by the circuit from active mode to sleep mode and vice versa, the switch from sleep mode to active mode comprising:
turning on the TG or the pass transistor;
turning off the TG or the pass transistor after a predetermined period of time has lapsed; and
turning on the first and second sleep transistors after turning off the TG or the pass transistor; and
switching the circuit from active mode to sleep mode, the switch from active mode to sleep mode comprising:
turning off the first and second sleep transistors;
turning on the TG or the pass transistor after turning off the sleep transistors; and
turning off the TG or the pass transistor after a predetermined period of time has lapsed.

35. The method of claim 34, wherein the first sleep transistor is an n-channel metal-oxide-semiconductor (NMOS) transistor and the second sleep transistor is a p-channel metal-oxide-semiconductor (PMOS) transistor

36. The method of claim 34, wherein the TG comprises an n-channel metal-oxide-semiconductor (NMOS) transistor and a p-channel metal-oxide-semiconductor (PMOS) transistor, a source of the NMOS transistor being connected to a drain of the PMOS transistor, a drain of the NMOS transistor being connected to a source of the PMOS transistor.

37. The method of claim 34, wherein a size of the TG or the pass transistor maintains or reduces a wake-up time of the circuit.

38. The method of claim 34, wherein placement and sizing of the TG or pass transistor takes into account a wake-up delay, energy consumption due to mode transition, or both.

39. The method of claim 34, wherein placement and sizing of the TG or pass transistor takes into account ground bounce (GB) during transitions by the circuit from sleep mode to active mode.

40. The method of claim 34, wherein the circuit comprises a plurality of TGs or pass transistors.
